(19) United States
(12) Patent Application Publication
(10) Pub. No.: US 2010/0231545 A1
(43) Pub. Date: Sep. 16, 2010

(54) TOUCH PANEL AND METHOD FOR PRODUCING THE SAME

(75) Inventors: Kazuhisa INABA, Tokyo (JP); Noriyuki YASUDA, Tokyo (JP); Masutatsu MASHIMO, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/721,145

(22) Filed: Mar. 10, 2010

(30) Foreign Application Priority Data
Mar. 16, 2009 (JP) 2009-063159

(51) Int. Cl. G06F 3/041; H05K 3/10

(52) U.S. Cl. 345/173; 29/846

(57) ABSTRACT

The invention provides a touch panel that exhibits high strength at the joints with external circuits, and that does not require high-temperature treatment for formation of the joints. The touch panel of the invention comprises a pair of electrode members, each having a construction with a transparent base and a transparent conductive layer laminated on the transparent base, situated separate and opposing each other with their transparent conductive layers facing, wherein the electrode member has a body section and lead sections formed by protrusions of the transparent base and transparent conductive layer from an edge of the body section, and a pair of extraction electrodes are formed on the side of the transparent conductive layer opposite the transparent base, the pair of extraction electrodes opposing each other in the body section and each extending to the lead sections.

### BACKGROUND OF THE INVENTION

1. Field of the Invention

The present invention relates to a touch panel and to a method for producing it.

2. Related Background Art

Resistance film-type touch panels are known that have a structure with a pair of electrode members, each comprising a transparent conductive layer on a transparent base, laid together so that the transparent conductive layers are facing each other across a spacer or the like. In such touch panels, one of the electrode members is pressed to contact the other electrode member and create current between the transparent conductive layers, thereby allowing detection of the location that was pressed.

Such touch panels require connection of the transparent conductive layer with an external circuit for detection of current.

The connection has conventionally been made using a flexible printed circuit board (FPC) (see Japanese Unexamined Patent Publication No. 2003-29930 and Japanese Unexamined Patent Publication No. 2004-259640).

### SUMMARY OF THE INVENTION

However, since connection with an FPC requires connection of the FPC with the transparent conductive layer, the strength of the joint tends to be weakened. In addition, connection of the FPC usually requires treatment at relatively high temperature, and high-temperature treatment can cause expansion of the transparent base and cracking of the transparent conductive layer, thereby potentially resulting in poor characteristics of the transparent conductive layer, which may include a lack of uniform distribution of the resistance value in the in-plane direction.

The present invention has been accomplished in light of these circumstances, and its object is to provide a touch panel that exhibits high strength at joints with external circuits, and that does not require high-temperature treatment for formation of the joints, as well as a method for producing it.

In order to achieve this object, the touch panel of the invention is a touch panel comprising a pair of electrode members, each having a construction with a transparent base and a transparent conductive layer laminated on the transparent base, situated separate and opposing each other with their transparent conductive layers facing, wherein the electrode member has a body and lead sections formed by protrusions of the transparent base and transparent conductive layer from the edge of the body, and a pair of extraction electrodes are formed on the side of the transparent conductive layer opposite the transparent base, the pair of extraction electrodes opposing each other in the body and each extending to the lead sections.

Since the touch panel of the invention has extraction electrodes that extend out from the body section at the lead sections of the electrode members, it is possible to connect the transparent conductive layers with external circuits using the lead sections. The lead sections are formed integrally with the electrode members because each transparent base and transparent conductive layer composing the electrode member is protruding, and therefore the strength of the joint is not reduced as with connection using a conventional FPC, and high strength is exhibited when connection is made to external circuits. In addition, since the lead sections are formed integrally with the electrode member, there is no need for high-temperature treatment as with connection of FPCs and the characteristics are not impaired as a result.

Since the touch panel of the invention can be connected to an external circuit or the like by the lead sections formed integrally with the electrode members, it may be used as a unit with pre-formed joints, thus increasing the degree of freedom for application as a touch panel. Specifically, since the touch panel of the invention has the lead sections at the joints formed in an integral fashion, it can be mounted on any display device and simply connected by the lead sections, thus allowing the function of the touch panel to be easily incorporated into the display device. Also, since the lead sections at the joints are integrally formed, a panel that has been applied to one display device can be easily removed and applied to a different display device.

In the touch panel of the invention, the extraction electrodes formed on at least one of the electrode members may lead out in a manner wrapping around the edges of the lead sections from the transparent conductive layer side to the transparent base side. Since the extraction electrodes formed on the opposing electrode members are facing each other they will normally be positioned on opposite sides of the lead sections, but if extraction electrodes are leading out and wrapped around to the transparent base side of the lead sections as described above, they will be able to wrap around to the same side as the lead sections of the other extraction electrodes. Having the extraction electrodes arranged on the same side of the lead sections in this manner may be advantageous for connecting external circuits and the like with the lead sections of the touch panel.

The invention further provides a method for producing a touch panel, which comprises a first step of obtaining electrode members comprising a transparent conductive layer formed on a transparent base, and having a body section and lead sections formed by protrusion of the transparent base and transparent conductive layer from the edges of the body section, a second step of forming a pair of extraction electrodes on the side of the transparent conductive layer of the electrode member opposite the transparent base, so that they are situated opposing each other in the body section and each extend to the lead sections, and a third step of laying together a pair of electrode members on which extraction electrodes have been formed so that the transparent conductive layers are facing each other.

This method for producing a touch panel can satisfactorily produce a touch panel according to the invention having lead sections integrally formed with the electrode members. In addition, since the electrode members are formed with pre-formed lead sections in this method, there is no need for the high temperature treatment required when a connecting FPC or the like is provided afterwards. Deterioration in the characteristics caused by treatment for connection is thus drastically reduced.

In the production method of the invention, the transparent conductive layer is preferably formed by transfer or coating of a transparent conductive layer-forming material on the transparent base. This will allow a uniform transparent conductive layer to be formed more easily, and will also facilitate formation of the transparent conductive layer along the shapes of the lead sections when lead sections are provided by pre-working of the transparent base.

The extraction electrodes are preferably formed by coating the extraction electrode-forming material on the side of the transparent conductive layer in the electrode member opposite the transparent base side. This will facilitate formation of the extraction electrodes in the desired shapes, and is advantageous for forming extraction electrodes that lead out through the lead sections.

The extraction electrodes that lead out through the lead sections may also be formed by dipping the lead sections in the extraction electrode-forming material. This will permit formation of extraction electrodes on both sides of the lead sections in a more convenient manner, and will allow the extraction electrodes to be more easily led out to the transparent base side of the lead sections.

According to the invention it is possible to provide a touch panel that exhibits high strength at joints with external circuits, and that does not require high-temperature treatment for formation of the joints, as well as a method for producing it.

### BRIEF DESCRIPTION OF THE DRAWINGS

FIG. 1 is an exploded perspective view showing a touch panel according to a preferred embodiment.

FIG. 2 is a schematic perspective view showing parts of the lead sections of a touch panel.

FIG. 3 is a schematic perspective view showing parts of the lead sections of extraction electrodes leading out to the transparent base side.

### DESCRIPTION OF THE PREFERRED EMBODIMENTS

Preferred embodiments of the invention will now be explained with reference to the accompanying drawings. Throughout the explanation of the drawings, corresponding elements will be referred to by like reference numerals and will be explained only once. Also, the dimensional proportions depicted in the drawings are not necessarily limitative.

The construction of a touch panel according to a preferred embodiment will be explained first.

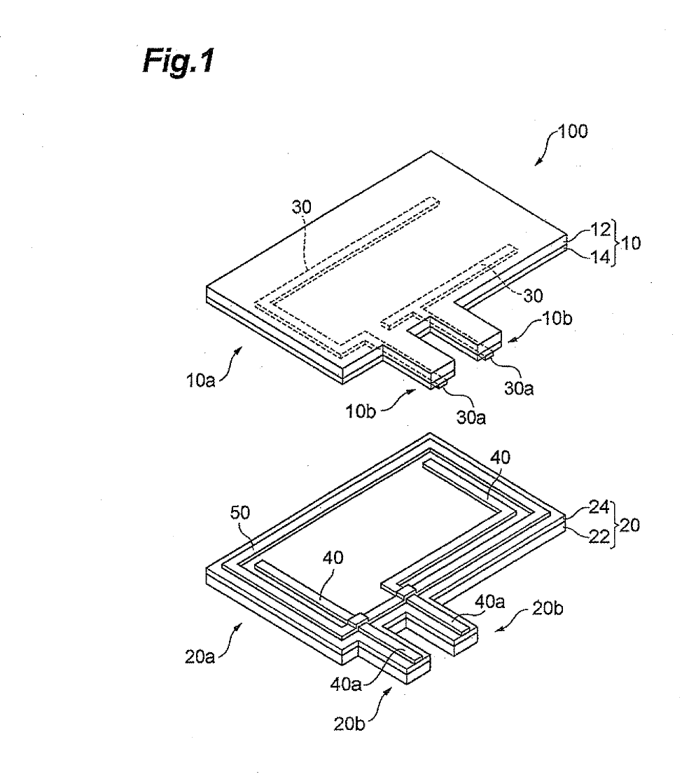

FIG. 1 is an exploded perspective view showing a touch panel according to the preferred embodiment. The touch panel 100 shown in FIG. 1 has a structure wherein an upper electrode member 10 comprising a transparent conductive layer 14 laminated on a transparent base 12 and a lower electrode member 20 comprising a transparent conductive layer 24 laminated on a transparent base 22 are situated in a mutually opposing manner with their transparent conductive layers 14, 24 facing each other.

The transparent bases 12, 22 are composed of a material that is transparent to visible light. As examples of the transparent bases 12, 22 there may be mentioned bases made of polyester resins such as polyethylene terephthalate (PET), polyolefin resins such as polyethylene and polypropylene, or polycarbonate resins, acrylic resins, norbornane-based resins (ARTON by JSR, ZEONOR by Zeon Corp., and the like), and polyethersulfone (PES). Glass may also be used instead of these resins. The material for the transparent bases 12, 22 is not limited to those mentioned above and may be a different type of transparent base material.

If resin films are used for the transparent bases 12, 22, the touch panel 100 will undergo shape deformation more easily and will have a smaller thickness and lighter weight, thus increasing the degree of design freedom for the display device in which the touch panel 100 is used.

The transparent conductive layers 14, 24 are composed of conductive materials that are transparent to visible light, such as a transparent conductive oxides, for example. As transparent conductive oxides there may be mentioned indium oxide or indium oxide doped with one or more elements selected from among tin, zinc and tellurium, tin oxide or tin oxide doped with one or more elements selected from among antimony, zinc and fluorine, zinc oxide or zinc oxide doped with one or more elements selected from among aluminum, gallium, indium and boron, and titanium oxide doped with one or more elements selected from among niobium, molybdenum and tantalum. Conductive polymers may also be used instead of oxides. Tin-doped indium oxide (ITO) is a suitable structural material for the transparent conductive layers 14, 24. The transparent conductive layers 14, 24 may also be layers with a structure in which powder composed of ITO or other transparent conductive particles is fixed with a resin.

The upper electrode member 10 and lower electrode member 20 are attached via a spacer 50 between the transparent conductive layers 14, 24. The spacer 50 is situated along the perimeter of the touch panel 100, and is composed of an insulating resin or the like. The spacer 50 causes the upper electrode member 10 and lower electrode member 20 to be placed apart in such a manner that the transparent conductive layer 14 and transparent conductive layer 24 are not in contact in the absence of pressing force.

Although the spacer 50 is provided around approximately the entire perimeter of the touch panel 100 in this embodiment, it may be provided only around part of the edges instead of the entire perimeter of the touch panel 100, and if necessary it may even be provided in the interior. Also, while not shown, a plurality of dot spacers may be provided on the inner surface of the transparent conductive layer 14 or 24 in the interior region of the upper electrode member 10 or lower electrode member 20.

The upper electrode member 10 has a form comprising a rectangular body section 10a and two lead sections 10b formed on one side of the body section 10a. The two lead sections 10b are formed by protrusion of the transparent base 12 and transparent conductive layer 14 from the body section 10a in the direction perpendicular to the side of the electrode member 10, and more specifically to the direction of lamination of the transparent base 12 and transparent conductive layer 14, and they are integral with the body section 10a.

Similarly, the lower electrode member 20 also has a rectangular body section 20a and two lead sections 20b formed by the transparent base 22 and transparent conductive layer 24 protruding from one side of the body section 20a. The two lead sections 10b of the upper electrode member 10 and the two lead sections 20b of the lower electrode member 20 are formed so as to lead out from the same side of the touch panel 100. The lead section 10b and lead section 20b have an alternate placement so that they do not overlap.

A pair of extraction electrodes 30 composed of a conducting material such as a metal (for example, Ag) are provided on the inner surface of the transparent conductive layer 14 in the upper electrode member 10. The pair of extraction electrodes 30 are formed in the body section 10a parallel along a pair of opposing sides of the touch panel 100. The pair of extraction electrodes 30 also have lead wires 30a that extend from the parallel formed sections to the lead sections 10b.

The pair of extraction electrodes 30 lead out to different lead sections 10b. That is, the extraction electrode 30 near the lead sections 10b has a lead wire 30a formed protruding from its side, extending from the body section 10a to a lead section 10b. Also, the extraction electrode 30 far from the lead sections 10b has a lead wire 30a formed running around the area near the edges of the body section 10a and extending to the other lead section 10b.

A pair of extraction electrodes 40 are also formed on the inner surface of the transparent conductive layer 24 of the lower electrode member 20, similar to the upper electrode member 10. The pair of extraction electrodes 40 are formed in the body section 20a parallel along a different pair of opposing sides of the touch panel 100 than the extraction electrodes 30 of the upper electrode member 10. That is, the sections of the extraction electrodes 30 and the extraction electrodes 40 formed parallel to the body sections 10a, 20a are in a positional relationship with mutually crossing, and preferably orthogonal, directions.

The pair of extraction electrodes 40 of the lower electrode member 20, as well, each have lead wires 40a extending from the sections parallel to the body section 20a to the lead sections 20b, and running around the area near the edges of the body section 20a if necessary. The pair of extraction electrodes 40 lead out to different lead sections 20b by their respective lead wires 40a.

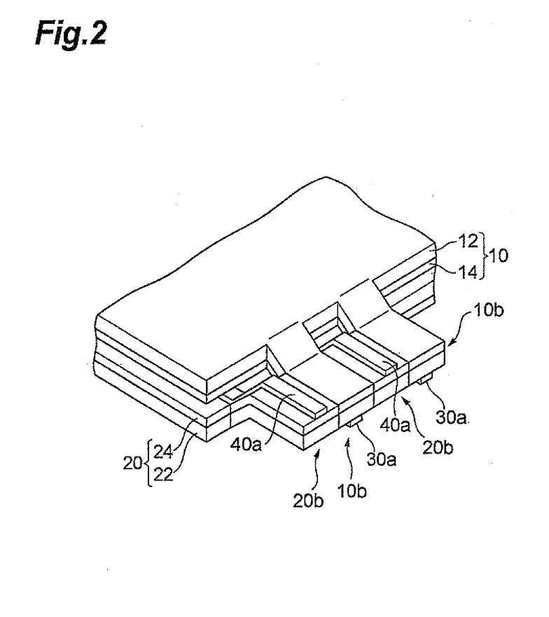

FIG. 2 is a schematic perspective view showing part of the lead sections of a touch panel. The spacer 50 is not shown in FIG. 2 for simplicity.

In the touch panel 100 shown in FIG. 2, the lead sections 10b where the extraction electrodes 30 lead out and the lead sections 20b where the extraction electrodes 40 lead out are bent so that their tips are situated on the same plane. A single terminal is thus formed by the two lead sections 10b and the two lead sections 20b. This facilitates connection of an external circuit or the like for the touch panel 100.

When a touch panel 100 having such a construction is used, the upper electrode member 10 and lower electrode member 20 function as a movable side and a fixed side, respectively, and the touch panel 100 may be placed on a display device so that the movable upper electrode member 10 is on the surface. In the normal state of the touch panel 100, the upper electrode member 10 and lower electrode member 20 are not in contact and no current flows between them.

When the movable upper electrode member 10 is pressed during use, however, the transparent conductive layers 14, 24 of both electrode members 10, 20 contact at that section and current flow takes place there. In this state, the voltage between the pair of extraction electrodes 30 formed on the upper electrode member 10 or between the pair of extraction electrodes 40 formed on the lower electrode member 20 is detected at the electrode to which the voltage has been applied. This detected voltage value can be used to determine the distance from the pair of extraction electrodes 30, 40 that are parallel in the body sections 10a, 20a to the location where electrification has occurred. The pressing location can thus be identified.

The lead sections 10b, 20b, where the extraction electrodes 30, 40 lead out, protrude from the body sections 10a, 20a of the touch panel 100, collectively forming a terminal. The touch panel 100 can therefore be connected externally by this terminal, thus eliminating the need for separate connection with an FPC as in the prior art. Such voltage data can therefore be easily extracted from the touch panel 100, so that a touch panel function can be more easily imparted to any display device.

A preferred method for producing a touch panel 100 having the structure described above will now be explained.

First, an upper electrode member 10 and a lower electrode member 20 are each prepared for production of the touch panel 100. Since they can be formed in the same manner, the upper electrode member 10 alone will be described as an example.

The upper electrode member 10 can be obtained by preparing a transparent base 12 and forming a transparent conductive layer 14 on it. Formation of the transparent conductive layer 14 on the transparent base 12 may be accomplished as appropriate depending on the structural material of the transparent conductive layer 14. For example, an ITO layer may be formed by a physical build-up method such as vapor deposition or sputtering. Alternatively, a layer (sheet) made of ITO or the like may be pre-formed and transferred onto the transparent base 12. For a layer having transparent conductive particles fixed in the resin, the layer may be formed by dispersing the particles in a solvent, directly coating the solution onto the transparent base 12 by a prescribed method, and drying. For formation of a transparent conductive layer 14 composed of a conductive polymer, the conductive polymer is preferably coated onto the transparent base 12 and dried by some method, as mentioned above.

The upper electrode member 10 also comprises a body section 10a and lead sections 10b, as above. The upper electrode member 10 with this shape can be obtained by forming the transparent conductive layer 14 on the transparent base 12 and then cutting it to the required shape. After the transparent base 12 has been cut to the shape corresponding to the body section 10a and lead sections 10b, the transparent conductive layer 14 may be formed on its surface. In this case, the transparent conductive layer 14 can be easily matched to the shape of the transparent base 12 by forming the material for the transparent conductive layer 14 onto the transparent base 12 using a method of transfer or coating. An upper electrode member 10 comprising the integrally formed body section 10a and lead sections 10b can thus be obtained.

Either or both the upper/lower electrode members 10, 20 may have dot spacers provided on their transparent conductive layers 14, 24 if necessary. A dot spacer is formed from a photocuring resin, by placing the resin at a prescribed location and curing it with light, for example.

Next, extraction electrodes 30, 40 having prescribed patterns are formed on the respective surfaces of the transparent conductive layers 14, 24. The extraction electrodes 30, 40 can also be formed by appropriate methods depending on their structural materials. The extraction electrodes 30, 40 are most preferably formed by coating the material for the extraction electrodes, such as conductive paste, by a printing method such as screen printing, and then drying it.

Coating in this manner will allow the conductive paste to easily adopt the prescribed shape. It is therefore advantageous for forming extraction electrodes 30, 40 with complex shapes with the lead wires 30a, 30b. The conductive paste used may be a mixture of a material such as the metal for the extraction electrodes 30, 40, with a binder or solvent.

After the attachment described below, an adhesive spacer 50 is situated on either or both the upper/lower electrode members 10, 20 on which the extraction electrodes 30, 40 have been formed. The adhesive is formed on the transparent conductive layer 14 or 24 of the upper electrode member 10 or lower electrode member 20, in such a manner that the desired spacer 50 shape is obtained. The adhesive is preferably formed by coating with a dispenser or by screen printing, and it may be dried after coating if necessary. The adhesive for the spacer 50 may be provided on both the upper and lower electrode members 10, 20, and it may be formed separately so that the spacer 50 as a whole is formed following the shapes of the extraction electrodes 30, 40.

The upper electrode member 10 and lower electrode member 20, on which the extraction electrodes 30, 40 and the adhesive for the spacer 50 have been formed in the manner described above, are placed together with their transparent conductive layers 14, 24 facing each other and are attached via the adhesive. The upper electrode member 10 and lower electrode member 20 are placed so that the extraction electrodes 30, 40 are in the prescribed positional relationship mentioned above (the directions of the body sections are perpendicular). Such attachment by itself allows the adhesive to function as the spacer 50, but if necessary the adhesive may be dried or cured as well. A touch panel 100 having the construction described above is thus obtained.

Preferred embodiments of the touch panel and method for producing it were described above, but the invention is not necessarily limited to these embodiments and may be appropriately modified within ranges that still maintain the gist of the invention.

For example, the extraction electrodes 30, 40 in the embodiment described above were described as leading out only on one side of the respective lead sections 10b, 20b (the transparent conductive layer 14, 24 sides). Therefore, when the lead sections 10b and lead sections 20b are combined as a single terminal, the extraction electrodes 30 and extraction electrodes 40 are on opposite sides (see FIG. 2). As an alternative for the invention, however, at least one pair of extraction electrodes 30, 40 may lead out in the lead sections 10b, 20b from the transparent conductive layer 14, 24 side to the transparent base 12, 22 side, by wrapping around the edges of the lead sections 10b, 20b.

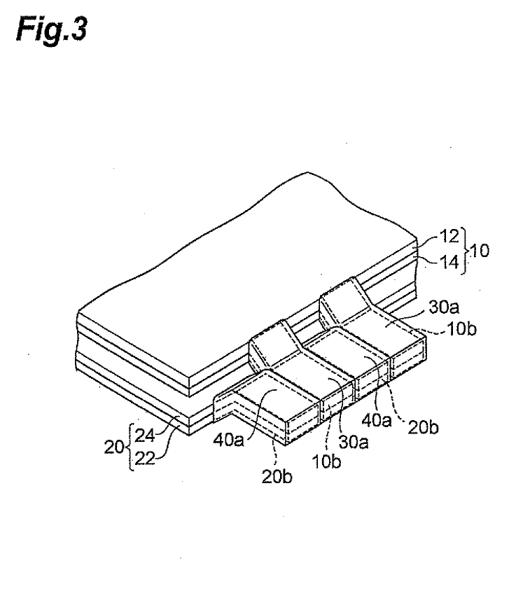

FIG. 3 is a schematic perspective view showing parts of the lead sections of extraction electrodes leading out to the transparent base side. The lead sections 10b, 20b shown in FIG. 3 are entirely covered by the extraction electrodes 30 (lead wire 30a), 40 (lead wire 40a). The extraction electrodes 30, 40 lead out around the lead sections 10b, 20b so that they cover their surfaces not only on the transparent conductive layer 14, 24 sides but also the transparent base 12, 22 sides. With this construction it is possible to connect both the extraction electrodes 30, 40 on the same side when the lead sections 10b and 20b are combined as a single terminal. External connection by the lead sections 10b, 20b can often be facilitated as a result.

The lead sections 10b, 20b having this construction can be formed by dipping the lead section 10b, 20b portions in the material for the extraction electrodes 30, 40. This will allow easier formation of the extraction electrodes 30, 40 covering the entirety of the lead sections 10b, 20b.

With dipping, the extraction electrodes 30, 40 at the body section 10a, 20b portions can be formed by the coating described above. Also, when the extraction electrodes 30, 40 of the body sections 10a, 20a are formed by coating, they may be led out to at least parts of the lead sections 10b, 20b. This will permit more satisfactory electrical connection between the extraction electrodes 30, 40 formed on the body sections 10a, 20a and the extraction electrodes 30, 40 formed covering the lead sections 10b, 20b.

The method for forming the extraction electrodes 30, 40 up to the transparent base 12, 22 sides of the lead sections 10b, 20b is not limited to dipping. For example, simple application can be used to form the extraction electrodes 30, 40 so that they wrap around the lead sections 10b, 20b. Also, in cases where the extraction electrodes 30, 40 are to wrap around from the transparent conductive layer 14, 24 sides to the transparent base 12, 22 sides, instead of covering the entirety of the lead sections 10b, 20b with the extraction electrodes 30, 40 as described above, the extraction electrodes 30, 40 that are already leading straight out as shown in FIGS. 1 and 2 may continue to the opposite side by wrapping around the sides (edges) of the lead sections 10b, 20b.

Also, while the upper electrode member 10 and lower electrode member 20 each had two lead sections 10b and lead sections 20b in the embodiment described above, this is not restrictive and the number of lead sections formed on each electrode member may be 1, or 3 or more, depending on the number of electrodes required to lead out from the body section. Also, two or more extraction electrodes may lead out from a single lead section. When many lead sections are present in the electrode members, extraction electrodes may not be leading out to some of the lead sections.

Also, while all of the lead sections 10b, 20b were formed protruding from the same side of the touch panel 100 for this embodiment, this is not restrictive and several lead sections may be provided on different sides of the touch panel, depending on the manner in which the touch panel is to be connected.

What is claimed is:

1. A touch panel comprising a pair of electrode members, each having a construction with a transparent base and a transparent conductive layer laminated on the transparent base, situated separate and opposing each other with their transparent conductive layers facing, wherein:
each electrode member has a body section and a lead section formed by protrusion of the transparent base and transparent conductive layer from the edge of the body section,
and a pair of extraction electrodes are formed on the side of the transparent conductive layer opposite the transparent base, the pair of extraction electrodes opposing each other in the body section and each extending to the lead sections.

2. A touch panel according to claim 1, wherein the extraction electrodes formed on at least one of the electrode members lead out at the lead sections in a manner wrapping around the edges of the lead sections, from the transparent conductive layer side to the transparent base side.

3. A method for producing a touch panel, comprising:
a first step of obtaining electrode members each comprising a transparent conductive layer formed on a transparent base, and having a body section and lead sections formed by protrusion of the transparent base and transparent conductive layer from the edges of the body section,
a second step of forming a pair of extraction electrodes on the side of the transparent conductive layer of the electrode member opposite the transparent base, so that they are situated opposing each other in the body section and each extend to the lead sections, and
a third step of laying together a pair of electrode members on which extraction electrodes have been formed so that the transparent conductive layers are facing each other.

4. The method for producing a touch panel according to claim 3, wherein the transparent conductive layer is formed by transfer or coating of the material for the transparent conductive layer onto the transparent base.

5. The method for producing a touch panel according to claim 3, wherein the extraction electrodes are formed by coating the material for the extraction electrodes on the side of the transparent conductive layer opposite the transparent base side.

6. The method for producing a touch panel according to claim 3, wherein the extraction electrodes leading out to the lead sections are formed by dipping the lead sections in the material for the extraction electrodes.
